(19) United States
(12) Patent Application Publication
(10) Pub. No.: US 2016/0242283 A1
(43) Pub. Date: Aug. 18, 2016

(54) WIRING BOARD, AND MOUNTING STRUCTURE AND LAMINATED SHEET USING THE SAME

(71) Applicant: KYOCERA CORPORATION, Koyoto (JP)

(72) Inventor: Katsura HAYASHI, Kyoto-shi (JP)

(73) Assignee: KYOCERA Corporation, Kyoto-shi, Kyoto (JP)

(21) Appl. No.: 15/029,335

(22) PCT Filed: Oct. 29, 2014
(86) PCT No.: PCT/JP2014/078836

§ 371 Date: Apr. 14, 2016

(30) Foreign Application Priority Data
Oct. 29, 2013 (JP) 2013-223991

(51) Int. Cl. H05K 1/11; H05K 1/03

(52) U.S. Cl. CPC H05K 1/11; H05K 1/0306; H05K 1/0313; H05K 2201/068; H05K 2201/0326

(57) ABSTRACT

A wiring board excellent in electrical reliability is provided. A wiring board includes a first resin layer; an inorganic insulating layer disposed on the first resin layer; a second resin layer disposed on the inorganic insulating layer; and a conductive layer disposed on the second resin layer. The inorganic insulating layer has a first region located in a vicinity of the second resin layer and a second region located on a side opposite to a second resin layer side of the first region. A content ratio of second inorganic insulating particles in the first region is lower than a content ratio of second inorganic insulating particles in the second regions.

### TECHNICAL FIELD

The present invention relates to a wiring board used for electronic apparatuses (for example, various kinds of audiovisual apparatuses, home electrical appliances, communication apparatuses, and computer apparatuses and peripherals thereof), and to a mounting structure and a laminated sheet using the same.

### BACKGROUND ART

Conventionally, a mounting structure in which electronic components are mounted on a wiring board has been used for electronic apparatuses.

As this wiring board, for example, Patent Literature 1 describes a structure provided with an inorganic insulating layer (ceramic layer) and a conductive layer (nickel thin layer) disposed on the inorganic insulating layer.

### CITATION LIST

### Patent Literature

Patent Literature 1: Japanese Unexamined Patent Publication JP-A 04-122087(1992)

### SUMMARY OF INVENTION

### Technical Problem

However, according to Patent Literature 1, for example, when heat is applied to the mounting structure while an electronic component is being mounted or operating, since the thermal expansion coefficients of the wiring board and the electronic component are different, stress is applied to the wiring board, and this sometimes causes a crack in the inorganic insulating layer. If this crack extends to reach the conductive layer, disconnection occurs in the conductive layer. This sometimes reduces the electrical reliability of the wiring board.

An object of the invention is to provide a wiring board excellent in electrical reliability, and a mounting structure and a laminated sheet using the same.

### Solution to Problem

According to one embodiment of the invention, a wiring board includes a first resin layer; an inorganic insulating layer disposed on the first resin layer; a second resin layer disposed on the inorganic insulating layer; and a conductive layer disposed on the second resin layer, the inorganic insulating layer containing a plurality of first inorganic insulating particles partly connected to each other and having a particle diameter of not less than 3 nm and not more than 15 nm, a plurality of second inorganic insulating particles existing with the first inorganic insulating particles in between and having a particle diameter of not less than 35 nm and not more than 110 nm, a resin portion disposed in a gap between the plurality of first inorganic insulating particles, the inorganic insulating layer having a first region located in a vicinity of the second resin layer and a second region located on a side opposite to a second resin layer side of the first region, and a content ratio of the second inorganic insulating particles in the first region being lower than a content ratio of the second inorganic insulating particles in the second region.

According to one embodiment of the invention, a mounting structure includes the above-described wiring board; and an electronic component mounted on the wiring board and electrically connected to the conductive layer.

According to one embodiment of the invention, a laminated sheet includes a support sheet; an uncured resin layer disposed on the support sheet; and an inorganic resin layer disposed on the uncured resin layer, the inorganic insulating layer containing a plurality of first inorganic insulating particles partly connected to each other and having a particle diameter of not less than 3 nm and not more than 15 nm, and a plurality of second inorganic insulating particles existing with the first inorganic insulating particles in between and having a particle diameter of not less than 35 nm and not more than 110 nm, the inorganic insulating layer having a first region located in a vicinity of the uncured resin layer and a second region located on a side opposite to a uncured resin layer side of the first region, and a content ratio of the second inorganic insulating particles in the first region being lower than a content ratio of the second inorganic insulating particles in the second region.

### Advantageous Effects of Invention

According to the wiring board of the invention, since the content ratio of the second inorganic insulating particles in the first region is lower than the content ratio of the second inorganic insulating particles in the second region, crack occurrence in the first region of the inorganic insulating layer located in the vicinity of the second resin layer can be reduced. Thereby, a wiring board excellent in electrical reliability can be obtained.

According to the mounting structure of the invention, since the above-described wiring board is provided, a mounting structure using a wiring board excellent in electrical reliability can be obtained.

According to the laminated sheet of the invention, since the above-described wiring board can be produced by using this laminated sheet, a wiring board excellent in electrical reliability can be produced.

### BRIEF DESCRIPTION OF DRAWINGS

FIG. 1(a) is a cross-sectional view obtained by cutting a mounting structure according to an embodiment of the invention in a thickness direction thereof, and FIG. 1(b) is an enlarged cross-sectional view showing a part R1 in FIG. 1(a);

FIG. 2(a) is an enlarged cross-sectional view showing a part R2 in FIG. 1(b) and FIG. 2(b) is an enlarged cross-sectional view showing a part R3 in FIG. 1(b);

FIG. 3(a) is an enlarged cross-sectional view showing a part R4 in FIG. 2(a) and FIG. 3(b) is an enlarged cross-sectional view showing a part R5 in FIG. 2(a);

FIGS. 4(a) to (c) are cross-sectional views explaining a method of producing the mounting structure shown in FIG. 1(a), and FIG. 4(d) is an enlarged cross-sectional view showing a part, in FIG. 4(c), corresponding to the part R4 of FIG. 2(a);

FIG. 5 (a) is a cross-sectional view explaining a method of producing the mounting structure shown in FIG. 1(a), FIG. 5(b) is an enlarged cross-sectional view showing a part, in FIG. 5(a), corresponding to the part R4 of FIG. 2(a), FIG. 5(c) is a cross-sectional view explaining a method of producing the mounting structure shown in FIG. 1(a), and FIG. 5(d) is an enlarged cross-sectional view showing a part, in FIG. 5(c), corresponding to the part R4 of FIG. 2(a); and

FIGS. 6 (a) to (d) are cross-sectional views explaining a method of producing the mounting structure shown in FIG. 1(a).

### DESCRIPTION OF EMBODIMENTS

Hereinafter, a mounting structure provided with a wiring board according to an embodiment of the invention will be described in detail with reference to the drawings.

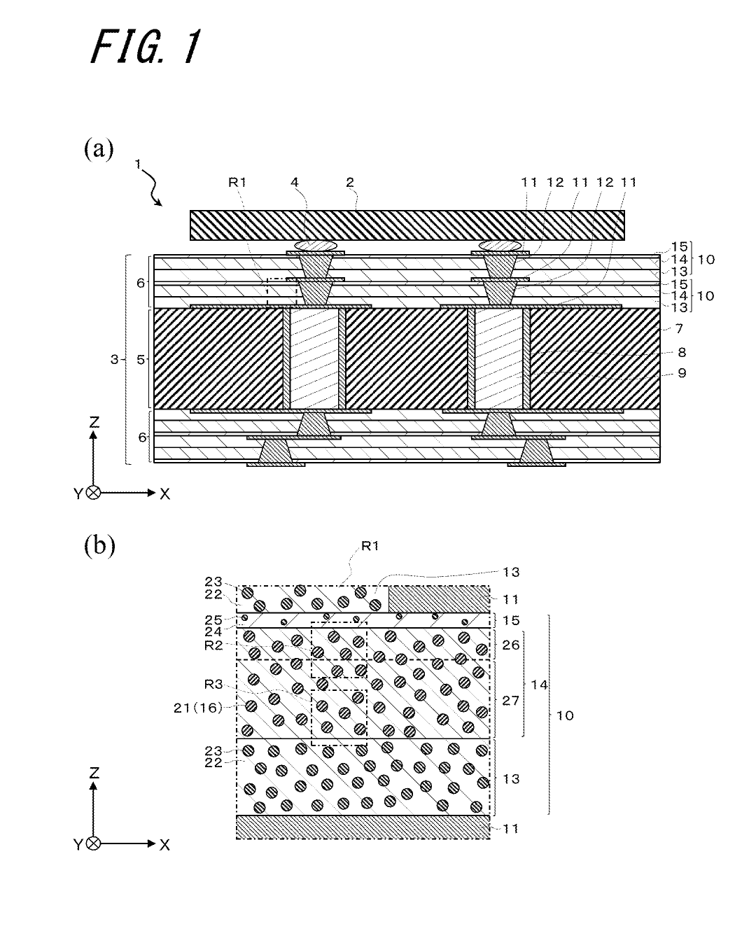

A mounting structure 1 shown in FIG. 1(a) is used in electronic apparatuses such as various kinds of audiovisual apparatuses, home electrical appliances, communication apparatuses, computer apparatuses or peripherals thereof. This mounting structure 1 includes an electronic component 2 and a wiring board 3 on which the electronic component 2 is mounted.

The electronic component 2 is, for example, a semiconductor element such as an IC or an LSI, or an elastic wave device such as a surface acoustic wave (SAW) device or a film bulk acoustic resonator (FBAR). This electronic component 2 is flip-chip mounted on the wiring board 3 through a bump 4 formed of a conductive material such as solder.

The wiring board 3 has a function of supporting the electronic component 2 and supplying the electronic component 2 with power and signals for driving or controlling the electronic component 2. This wiring board 3 includes a core substrate 5 and a pair of buildup layers 6 formed on the upper and lower surfaces of the core substrate 5.

The core substrate 5 provides electrical continuity between the pair of buildup layers 6 while enhancing the rigidity of the wiring board 3. This core substrate 5 includes a substrate 7 supporting the buildup layers 6, a tubular through hole conductor 8 disposed in a through hole passing through the substrate 7 in the thickness direction thereof, and a columnar insulator 9 surrounded by the through hole conductor 8.

The substrate 7 makes the wiring board 3 high in rigidity and low in thermal expansion coefficient. This substrate 7 contains, for example, a resin such as epoxy resin, a base material such as glass cloth covered with the resin and filler particles formed of silicon oxide or the like dispersed in the resin.

The through hole conductor 8 electrically connects the pair of buildup layers 6. This through hole conductor 8 contains a conductive material such as copper.

The insulator 9 is filled in the space surrounded by the through hole conductor 8. This insulator 9 contains a resin such as epoxy resin.

On the upper and lower surfaces of the core substrate 5, the pair of buildup layers 6 are formed as mentioned above. Of the pair of buildup layers 6, one buildup layer 6 connects with the electronic component 2 through the bump 4, and the other buildup layer 6 connects with an external circuit, for example, through a solder ball (not shown).

The buildup layers 6 include a plurality of insulating layers 10 having via holes passing therethrough in the thickness direction (Z direction) thereof, a plurality of conductive layers 11 disposed partially on the substrate 7 or on the insulating layers 10, and a plurality of via conductors 12 adhering to the inner walls of the via holes and connecting with the conductive layers 11.

The insulating layers 10 function as insulating members between the conductive layers 11 apart from each other in the thickness direction or in a main surface direction (an X-Y plane direction) and insulating members between the via conductors 12 apart from each other in the main surface direction of. The insulating layers 10 include a first resin layer 13, an inorganic insulating layer 14 disposed on the first resin layer 13, and a second resin layer 15 disposed on the inorganic insulating layer 14.

The first resin layer 13 functions as a bonding member between the insulating layers 10. Moreover, part of the first resin layer 13 is disposed between the conductive layers 11 apart from each other in the main surface direction, and functions as an insulating member between the conductive layers 11.

The thickness of the first resin layer 13 is, for example, not less than 3 μm and not more than 30 μm. The Young's modulus of the first resin layer 13 is, for example, not less than 0.2 GPa and not more than 20 GPa. The thermal expansion coefficient of the first resin layer 13 in each direction is, for example, not less than 20 ppm/° C. and not more than 50 ppm/° C. The Young's modulus of the first resin layer 13 is measured by a method pursuant to ISO14577-1:2002 by using Nano Indenter XP manufactured by MTS Systems Corporation. The thermal expansion coefficient of the first resin layer 13 is measured by a measurement method pursuant to JIS K7197-1991 by using a commercially available TMA (Thermo-Mechanical Analysis) apparatus. Hereinafter, the Young's modulus and thermal expansion coefficient of each member are measured similarly to those of the first resin layer 13.

The first resin layer 13 contains, as shown in FIG. 1(b), a first resin 22 and a plurality of first filler particles 23 dispersed in the first resin 22. The content ratio of the first filler particles 23 in the first resin layer 13 is, for example, not less than 3% by volume and not more than 60% by volume. The content ratio of the first filler particles 23 in the first resin layer 13 may be measured by regarding as the content ratio (% by volume) the ratio of the area occupied by the first filler particles 23 in a given area of the first resin layer 13 on a cross section in the thickness direction of the wiring board 3. Hereinafter, the content ratio of the particles in each member is measured similarly to that of the first filler particles 23.

The first resin 22 is formed of a resin material such as epoxy resin, bismaleimide triazine resin, cyanate resin or polyimide resin, and is preferably formed of epoxy resin above all else. The Young's modulus of the first resin 22 is, for example, not less than 0.1 GPa and not more than 5 GPa. The thermal expansion coefficient of the first resin 22 in each direction is, for example, not less than 20 ppm/° C. and not more than 50 ppm/° C.

The first filler particles 23 are formed of an inorganic insulating material such as silicon oxide, aluminum oxide, aluminum nitride, aluminum hydroxide or calcium carbonate, and are preferably formed of silicon oxide above all else. The first filler particles 23 are, for example, spherical. The particle diameter of the first filler particles 23 is, for example, not less than 0.5 μm and not more than 5 μm.

The inorganic insulating layer 14, which is formed of an inorganic insulating material high in rigidity and low in thermal expansion coefficient compared with resin materials, makes the wiring board 3 low in thermal expansion coefficient and high in rigidity. As a consequence, the rigidity of the wiring board 3 is enhanced while the difference in thermal expansion coefficient between the wiring board 3 and the electronic component 2 is reduced, whereby when heat is applied to the mounting structure 1 while the electronic component 2 is being mounted or operating, warpage of the wiring board 3 can be reduced.

The thickness of the inorganic insulating layer 14 is, for example, not less than 3 μm and not more than 30 μm. The Young's modulus of the inorganic insulating layer 14 is higher than the Young's moduli of the first resin layer 13 and the second resin layer 15. The Young's modulus of the inorganic insulating layer 14 is, for example, not less than 10 GPa and not more than 50 GPa. The thermal expansion coefficient of the inorganic insulating layer 14 in each direction is lower than the thermal expansion coefficients of the first resin layer 13 and the second resin layer 15 in each direction. The thermal expansion coefficient of the inorganic insulating layer 14 in each direction is, for example, not less than 0 ppm/° C. and not more than 10 ppm/° C.

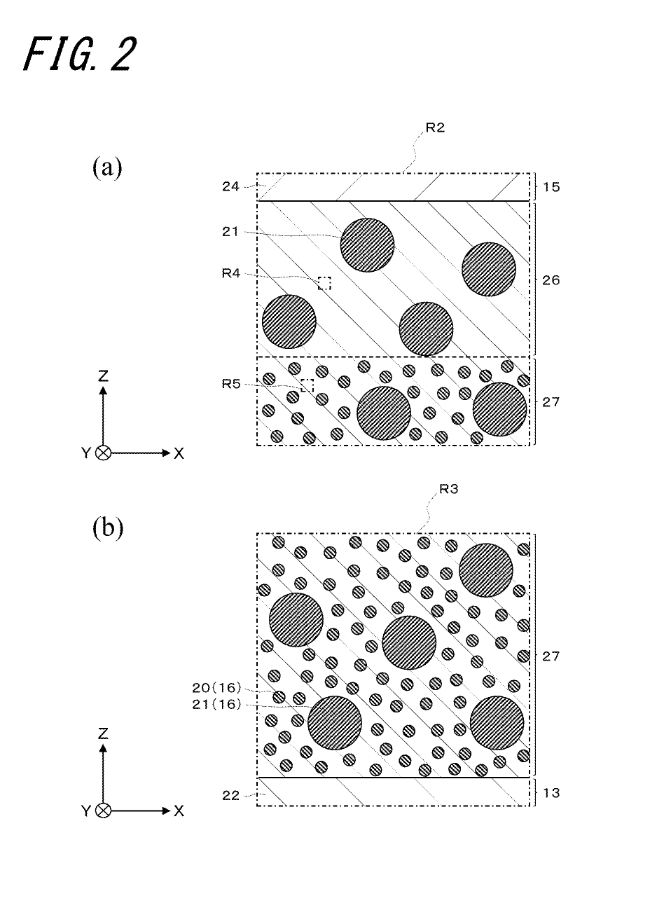

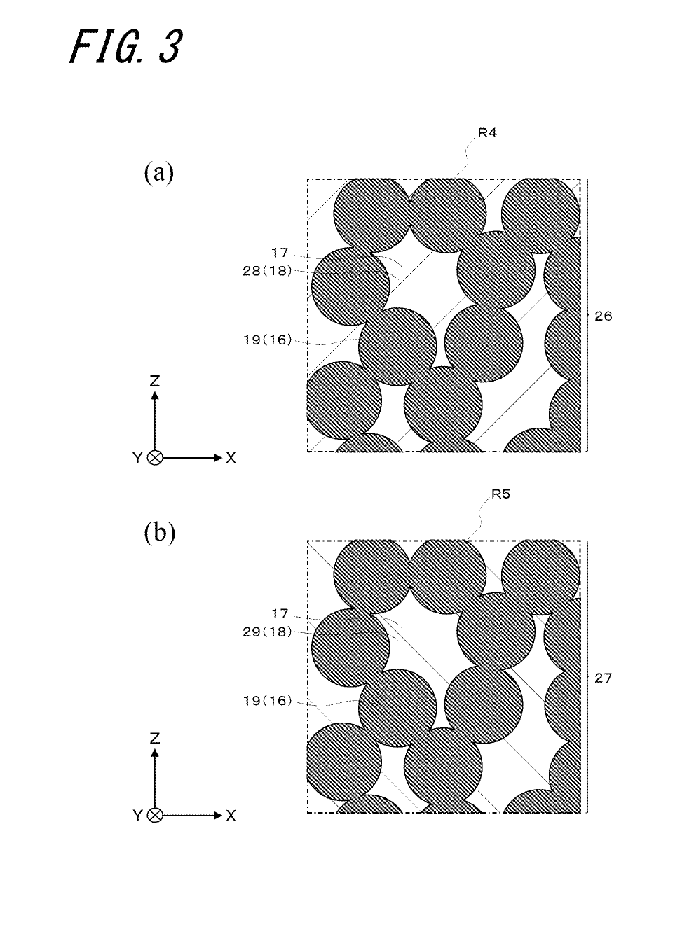

The inorganic insulating layer 14 contains, as shown in FIG. 2 and FIG. 3, a plurality of inorganic insulating particles 16 partly connected to each other and a resin portion 18 disposed in part of a gap 17 among the inorganic insulating particles 16. In the inorganic insulating layer 14, the inorganic insulating particles 16 are connected to each other to thereby form a porous body which is a three-dimensional net-like structure. The connection portions between the inorganic insulating particles 16 are constricted and form a neck structure.

The inorganic insulating particles 16, which are bound together and do not flow since they are partly connected to each other, enhance the Young's modulus of the inorganic insulating layer 14 and reduce the thermal expansion coefficient thereof in each direction. These inorganic insulating particles 16 contain a plurality of first inorganic insulating particles 19 partly connected to each other, a plurality of second inorganic insulating particles 20 larger in particle diameter than the first inorganic insulating particles 19 and apart from each other with the first inorganic insulating particles 19 in between, and a plurality of third inorganic insulating particles 21 larger in particle diameter than the first inorganic insulating particles 19 and the second inorganic insulating particles 20 and apart from each other with the first inorganic insulating particles 19 and the second inorganic insulating particles 20 in between.

The first inorganic insulating particles 19 function as connection members in the inorganic insulating layer 14. Moreover, the first inorganic insulating particles 19, which firmly connect as described later since they are small in particle diameter, can make the inorganic insulating layer 14 high in rigidity and low in thermal expansion coefficient. These first inorganic insulating particles 19 are formed of an inorganic insulating material such as silicon oxide, zirconium oxide, aluminum oxide, boron oxide, magnesium oxide or calcium oxide, and above all, silicon oxide is preferably used from the viewpoint of low thermal expansion coefficient and low dielectric tangent.

The first inorganic insulating particles 19 are, for example, spherical. The particle diameter of the first inorganic insulating particles 19 is not less than 3 nm and not more than 15 nm. Moreover, the Young's modulus of the first inorganic insulating particles 19 is, for example, not less than 40 GPa and not more than 90 GPa. Moreover, the thermal expansion coefficient of the first inorganic insulating particles 19 in each direction is, for example, not less than 0 ppm/° C. and not more than 15 ppm/° C. The particle diameter of the first inorganic insulating particles 19 is obtained by measuring the maximum diameter appearing on a cross section in the thickness direction of the wiring board 3. Hereinafter, the particle diameter of each member is measured similarly to that of the first inorganic insulating particles 19.

The second inorganic insulating particles 20 reduce crack extension in the region between the third inorganic insulating particles 21. That is, when a crack extends to reach the second inorganic insulating particles 20 in the region between the third inorganic insulating particles 21, it necessarily detours around the second inorganic insulating particles 20 which are large in average particle diameter, so that the extension of the crack can be reduced. Some of the second inorganic insulating particles 20 connect with the first inorganic insulating particles 19, and the plurality of second inorganic insulating particles 20 bond together through the first inorganic insulating particles 19. As the second inorganic insulating particles 20, particles of a material and properties similar to those of the first inorganic insulating particles 19 may be used. The second inorganic insulating particles 20 are, for example, spherical. The particle diameter of the second inorganic insulating particles 20 is not less than 35 nm and not more than 110 nm.

The third inorganic insulating particles 21 further reduce crack extension in the inorganic insulating layer 14 than the second inorganic insulating particles 20. That is, since the particle diameter of the third inorganic insulating particles 21 is larger than the particle diameter of the second inorganic insulating particles 20, the energy necessary for detouring around the third inorganic insulating particles 21 is higher than the energy necessary for detouring the second inorganic insulating particles 20, so that the third inorganic insulating particles 21 can further reduce crack extension than the second inorganic insulating particles 20. Some of the third inorganic insulating particles 21 connect with the first inorganic insulating particles 19, and the plurality of third inorganic insulating particles 21 bond together through the first inorganic insulating particles 19. As the third inorganic insulating particles 21, particles of a material and properties similar to those of the first inorganic insulating particles 19 may be used. The third inorganic insulating particles 21 are, for example, spherical. The particle diameter of the third inorganic insulating particles 21 is, for example, not less than 0.5 μm and not more than 5 μm.

The gap 17 is an open pore, and has openings on one main surface and the other main surface of the inorganic insulating layer 14. Moreover, since the plurality of inorganic insulating particles 16 partly connected to each other form a porous body, at least part of the gap 17 is surrounded by the inorganic insulating particles 16 on a cross section in the thickness direction of the inorganic insulating layer 14.

The resin portion 18, which is formed of a resin material which more readily becomes elastically deformed than inorganic insulating materials, reduces the stress applied to the inorganic insulating layer 14 and reduces crack occurrence in the inorganic insulating layer 14.

The second resin layer 15, which is disposed between the inorganic insulating layer 14 and the conductive layer 11, enhances the strength of bonding between the inorganic insulating layer 14 and the conductive layer 11. Moreover, as described later, it reduces crack occurrence in the inorganic insulating layer 14. The thickness of the second resin layer 15 is, for example, not less than 0.1 μm and not more than 5 μm. The Young's modulus of the second resin layer 15 is, for example, not less than 0.05 GPa and not more than 5 GPa. The thermal expansion coefficient of the second resin layer 15 in each direction is, for example, not less than 20 ppm/° C. and not more than 100 ppm/° C.

The second resin layer 15 contains, as shown in FIG. 1(b), a second resin 24 and a plurality of second filler particles 25 dispersed in the second resin 24. The content ratio of the second filler particles 25 in the second resin layer 15 is lower than the content ratio of the first filler particles 23 in the first resin layer 13. As a consequence, the Young's modulus of the second resin layer 15 can be made lower than the Young's modulus of the first resin layer 13. The content ratio of the second filler particles 25 in the second resin layer 15 is, for example, not less than 0.05% by volume and not more than 10% by volume. The second resin layer 15 does not necessarily contain the second filler particles 25.

As the second resin 24, for example, a resin of a material and properties similar to those of the first resin 22 may be used. As the second filler particles 25, particles of a material and properties similar to those of the first filler particles 23 may be used. Moreover, the particle diameter of the second filler particles 25 is smaller than the particle diameter of the first filler particles 23. As a consequence, the Young's modulus of the second resin layer 15 can be made lower than the Young's modulus of the first resin layer 13. The particle diameter of the second filler particles 25 is, for example, not less than 0.05 μm and not more than 0.7 μm.

The conductive layers 11, which are apart from each other in the thickness direction or in the main surface direction, function as wiring such as grounding wiring, power supply wiring or signal wiring. The conductive layers 11 are formed of a conductive material such as copper, silver, gold, aluminum, nickel or chromium, and above all, copper is preferably used. The thickness of the conductive layers 11 is, for example, not less than 3 pm and not more than 20 pm. The thermal expansion coefficient of the conductive layers 11 in each direction is, for example, not less than 14 ppm/° C. and not more than 18 ppm/° C. The Young's modulus of the conductive layers 11 is, for example, not less than 70 GPa and not more than 150 GPa.

The via conductors 12 electrically connect the conductive layers 11 apart from each other in the thickness direction, and function as wiring together with the conductive layers 11. The via conductors 12 are filled in the via holes. The via conductors 12 are formed of a similar material to the conductive layers 11, and have similar properties.

In the present embodiment, as shown in FIG. 1, the wiring board 3 includes the first resin layer 13, the inorganic insulating layer 14 disposed on the first resin layer 13, the second resin layer 15 disposed on the inorganic insulating layer 14 and having a lower Young's modulus than the first resin layer 13, and the conductive layers 11 disposed on the second resin layer 15.

As a consequence, the second resin layer 15 more readily becomes elastically deformed than the first resin layer 13 since it is lower in Young's modulus than the first resin layer 13. For this reason, when stress is applied to the inside of the wiring board 3, for example, due to warpage of the wiring board 3, the second resin layer 15 disposed between the inorganic insulating layer 14 and the conductive layer 11 becomes elastically deformed, so that the stress applied to the inorganic insulating layer 14 can be reduced. Consequently, crack occurrence in the inorganic insulating layer 14 can be reduced.

Moreover, as shown in FIG. 2, the inorganic insulating layer 14 has a first region 26 located in the vicinity of the second resin layer 15 and a second region 27 located on a side opposite to a second resin layer 15 side of the first region 26. The content ratio of the second inorganic insulating particles 20 in the first region 26 is lower than the content ratio of the second inorganic insulating particles 20 in the second region 27. The vicinity of the second resin layer 15 is, for example, a region from the boundary between the second resin layer 15 and the inorganic insulating layer 14 to a thickness of 3 μm into the inorganic insulating layer 14.

As a consequence, since the content ratio of the second inorganic insulating particles 20 in the first region 26 is lower than the content ratio of the second inorganic insulating particles 20 in the second region 27, the content ratio of the resin portion 18 in the first region 26 can be made higher than the content ratio of the resin portion 18 in the second region 27. For this reason, the first region 26 located in the vicinity of the second resin layer 15 readily becomes elastically deformed. Consequently, when stress is applied to the inside of the wiring board 3, the stress caused between the second resin layer 15 which readily becomes elastically deformed and the inorganic insulating layer 14 which does not readily become elastically deformed can be reduced, so that crack occurrence in the inorganic insulating layer 14 can be reduced. Therefore, disconnection in the conductive layer 11 due to this crack is reduced, so that a wiring board 3 excellent in electrical reliability can be obtained.

Moreover, since the content ratio of the second inorganic insulating particles 20 in the second region 27 is higher than the content ratio of the second inorganic insulating particles 20 in the first region 26, crack extension can be reduced by the second inorganic insulating particles 20 in the second region 27 located on the side opposite to the second resin layer 15 side of the first region 26. Moreover, since the Young's modulus of the first resin layer 13 is higher than the Young's modulus of the second resin layer 15, the rigidity of the wiring board 3 can be enhanced. The magnitude relation between the content ratio of the resin portion 18 in the first region 26 and the content ratio of the resin portion 18 in the second region 27 can be determined by performing EDS analysis using a transmission electron microscope on a cross section in the thickness direction of the inorganic insulating layer 14.

In the present embodiment, the content ratio of the second inorganic insulating particles 20 in the first region 26 is not less than 0% by volume and not more than 10% by volume. The content ratio of the second inorganic insulating particles 20 in the second region 27 is more than 10% by volume and not more than 35% by volume. The content ratio of the first inorganic insulating particles 19 in the first region 26 and the second region 27 is not less than 15% by volume and not more than 45% by volume. The content ratio of the third inorganic insulating particles 21 in the first region 26 and the second region 27 is not less than 40% by volume and not more than 70% by volume.

Regarding the content ratios of the first, second and third inorganic insulating particles 19, 20 and 21 in the first and second regions 26 and 27, like the content ratio of the first filler particles 23 of the first resin layer 13, the ratios of the areas occupied by the first, second and third inorganic insulating particles 19, 20 and 21 in given areas of the first and second regions 26 and 27 on a cross section in the thickness direction of the wiring board 3 can be regarded as the content ratios (% by volume).

Here, the boundary between the first region 26 and the second region 27 defines a layered measurement region having a width of 2 μm at a pitch of 0.2 μm thickness from the boundary between the second resin layer 15 and the inorganic insulating layer 14 on a cross section in the thickness direction of the wiring board 3, the ratio of the area of the second inorganic insulating particles 20 to the total area in the measurement region is the content ratio, measurement is successively performed from the boundary in the thickness direction, the region up to the measurement region of not more than 10% by volume is the first region 26, and the region exceeding 10% by volume is the second region 27.

The first region 26 preferably contains, of the first inorganic insulating particles 19 and the second inorganic insulating particles 20, only the first inorganic insulating particles 19. As a consequence, since the first region 26 does not contain the second inorganic insulating particles 20, the first region 26 is made to more readily become elastically deformed, so that crack occurrence in the inorganic insulating layer 14 can be reduced. The fact that the first region 26 contains, of the first inorganic insulating particles 19 and the second inorganic insulating particles 20, only the first inorganic insulating particles 19, can be confirmed by observing five places of a cross section in the thickness direction of the inorganic insulating layer 14.

Further, the first region 26 preferably contains the third inorganic insulating particles 21. As a consequence, crack extension in the first region 26 can be reduced.

In the present embodiment, the thickness of the second resin layer 15 is smaller than the thickness of the first resin layer 13. As a consequence, by making small the thickness of the second resin layer 15 having a low Young's modulus, the rigidity of the wiring board 3 can be enhanced. Moreover, by making large the thickness of the first resin layer 13 with a high Young's modulus, the rigidity of the wiring board 3 can be enhanced. Moreover, since the first resin layer 13 is easily filled in between the conductive layers 11 apart from each other in the main surface direction, the performance of insulation between the conductive layers 11 can be enhanced. The thickness of the second resin layer 15 of the present embodiment is smaller than the thicknesses of the inorganic insulating layer 14 and the conductive layers 11.

In the present embodiment, the resin portion 18 has a first resin portion 28 disposed in the first region 26 and a second resin portion 29 disposed in the second region 27. The first resin portion 28 is formed of the resin forming the second resin layer 15, and this resin is part of the second resin 24. As a consequence, since part of the second resin layer 15 enters the gap 17 in the first region 26, the strength of bonding between the first region 26 and the second resin layer 15 can be enhanced by an anchor effect.

Moreover, the second resin portion 29 is formed of the resin forming the first resin layer 13, and this resin is part of the first resin 22. As a consequence, since part of the first resin layer 13 enters the gap 17 in the second region 27, the strength of bonding between the second region 27 and the first resin layer 13 can be enhanced by an anchor effect.

In the present embodiment, the thickness of the first region 26 is smaller than the thickness of the second region 27. As a consequence, the rigidity of the inorganic insulating layer 14 is enhanced, so that the rigidity of the wiring board 3 can be enhanced. The thickness of the first region 26 is, for example, not less than 0.2 μm and not more than 3 μm. The thickness of the second region 27 is, for example, not less than 3 μm and not more than 25 μm.

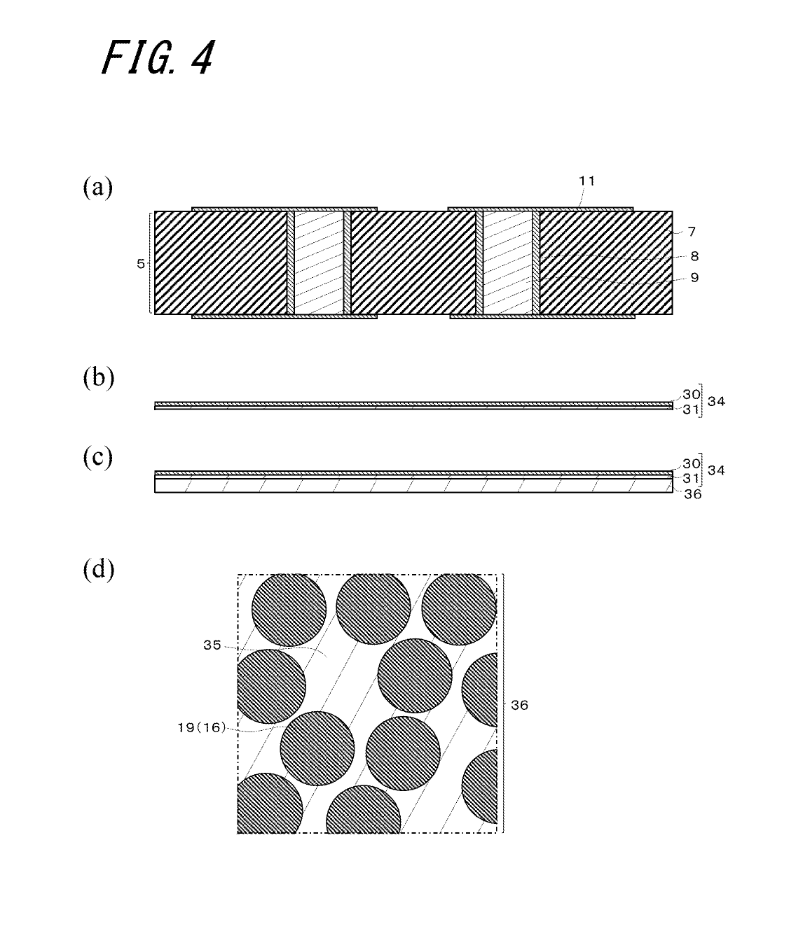

Next, a method of producing the mounting structure 1 described previously will be described with reference to FIG. 4 to FIG. 6.

(1) As shown in FIG. 4(a), the core substrate 5 is produced. Specifically, it is produced, for example, as follows:

The substrate 7 formed by curing a prepreg and a laminated plate formed of metallic foil such as copper foil disposed on both main surfaces of the substrate 7 are prepared. Then, a through hole is formed in the laminated plate by using laser processing, drilling or otherwise. Then, a conductive material is made to adhere to the inside of the through hole by using, for example, electroless plating, electrolytic plating, an evaporation method, sputtering or otherwise to form the tubular through hole conductor 8. Then, uncured resin is filled into the through hole conductor 8 and cured to thereby form the insulator 9. Then, after the conductive material is made to adhere onto the insulator 9 by using, for example, electroless plating, electrolytic plating or otherwise, patterning of the metal foil on the substrate 7 and the conductive material is performed to form the conductive layers 11. The core substrate 5 can be produced in the way described above.

(2) As shown in FIG. 4(b) to FIG. 6(a), a laminated sheet 33 is produced which includes a support sheet 30 formed of metal foil such as copper foil, a resin film such as a PET film or the like, a second uncured resin layer 31 disposed on the support sheet 30, the inorganic insulating layer 14 disposed on the second uncured resin layer 31 and a first uncured resin layer 32 disposed on the inorganic insulating layer 14. Specifically, it is produced, for example, as follows:

First, as shown in FIG. 4(b), a support sheet 34 with resin is prepared which has the support sheet 30 and the second uncured resin layer 31 disposed on the support sheet 30. The second uncured resin layer 31 contains an uncured resin which becomes the second resin 24 and the second filler particles 25.

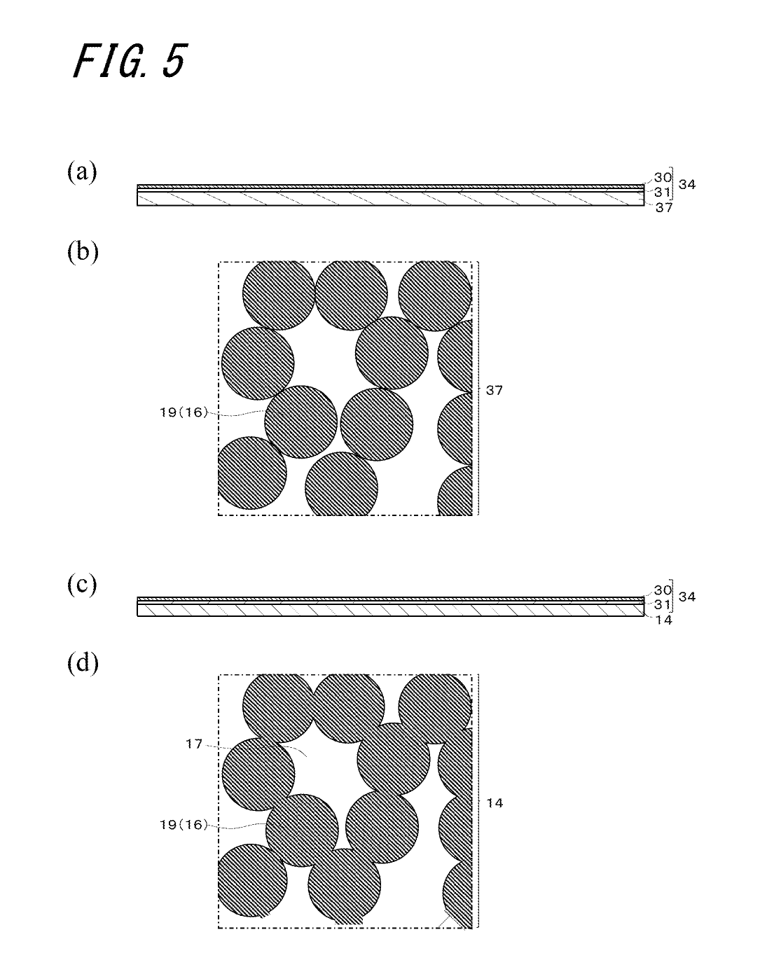

Then, as shown in FIG. 4(c) and FIG. 4(d), slurry 36 is prepared which has the inorganic insulating particles 16 and a solvent 35 in which the inorganic insulating particles 16 are dispersed, and the slurry 36 is applied to one main surface of the second uncured resin layer 31. Then, as shown in FIG. 5(a) and FIG. 5(b), the solvent 35 is evaporated from the slurry 36 so that the inorganic insulating particles 16 remain on the support sheet 30, thereby forming a powder layer 37 formed of the remaining inorganic insulating particles 16. In this powder layer 37, the first inorganic insulating particles 19 are in contact with each other at adjacent places. Then, as shown in FIG. 5(c) and FIG. 5(d), the powder layer 37 is heated to connect the adjoining first inorganic insulating particles 19 at the adjacent places, thereby forming the inorganic insulating layer 14.

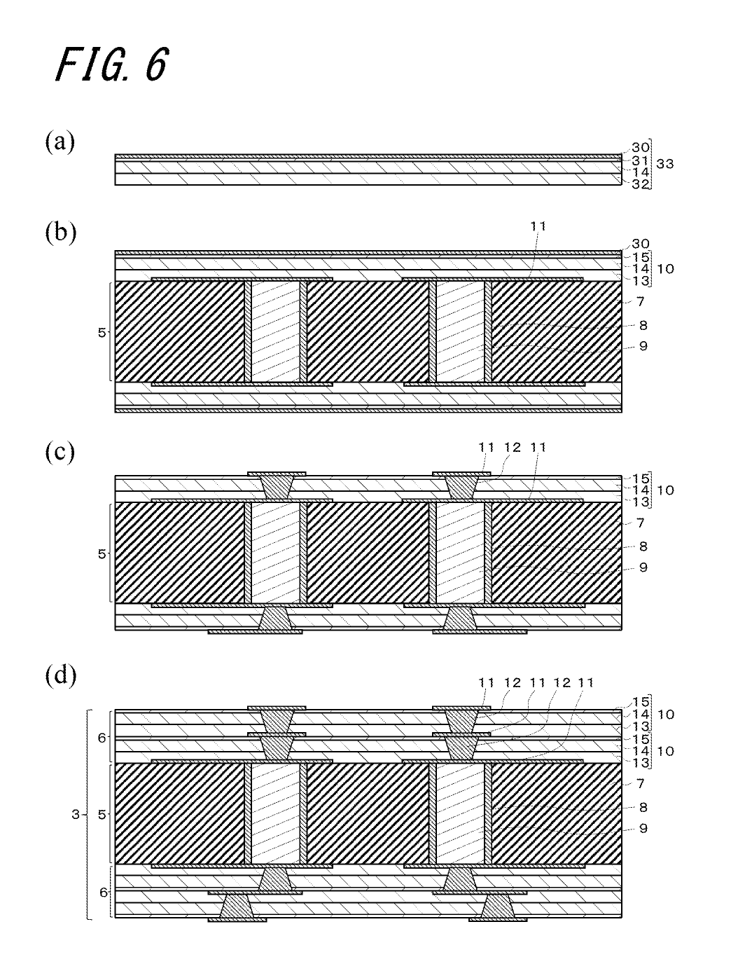

Then, as shown in FIG. 6(a), the first uncured resin layer 32 containing an uncured resin which becomes the first resin 22 and the first filler particles 23 is laminated onto the inorganic insulating layer 14, and the laminated inorganic insulating layer 14 and first uncured resin layer 32 are heated and pressurized in the thickness direction, thereby filling part of the first uncured resin layer 32 into the gap 17. The laminated sheet 33 can be produced in the way described above.

This laminated sheet 33 includes the support sheet 30, the second uncured resin layer 31 disposed on the support sheet 30, and the inorganic insulating layer 14 disposed on the second uncured resin layer 31. The inorganic insulating layer 14 contains the plurality of first inorganic insulating particles 19 partly connected to each other and having a particle diameter of not less than 3 nm and not more than 15 nm, and the plurality of second inorganic insulating particles 20 disposed apart from each other with the first inorganic insulating particles 19 in between and having a particle diameter of not less than 35 nm and not more than 110 nm.

In the laminated sheet 33 of the present embodiment, the inorganic insulating layer 14 has the first region 26 located in the vicinity of the second uncured resin layer 31 and the second region 27 located on a side opposite to a second uncured resin layer 31 side of the first region 26. The content ratio of the second inorganic insulating particles 20 in the first region 26 is lower than the content ratio of the second inorganic insulating particles 20 in the second region 27. Part of the second resin 24 of the second uncured resin layer 31 is disposed in the gap 17 between the first inorganic insulating particles 19 in the first region 26.

As a consequence, since the content ratio of the second inorganic insulating particles 20 in the first region 26 is lower than the content ratio of the second inorganic insulating particles 20 in the second region 27, the volume of the gap 17 in the first region 26 can be increased. Consequently, since the content ratio of the second resin 24 of the second uncured resin layer 31 in the first region 26 can be increased, the strength of bonding between the second uncured resin layer 31 and the inorganic insulating layer 14 can be enhanced. Therefore, the separation between the second uncured resin layer 31 and the inorganic insulating layer 14 in the laminated sheet 33 is reduced, so that the production efficiency of the wiring board 3 using the laminated sheet 33 can be enhanced.

In the present embodiment, when the slurry 36 is applied to the second uncured resin layer 31, part of the uncured resin of the second uncured resin layer 31 is dissolved or swelled by the solvent 35 in the slurry 36. As a consequence, a space with a size of approximately 3 to 15 nm is caused in the uncured resin. And when the solvent 35 is dried, the first inorganic insulating particles 19 having a small particle diameter in the slurry 36 precipitate and readily enter the space in the uncured resin, whereas the second inorganic insulating particles 20 having a large particle diameter do not readily enter the space in the uncured resin. Consequently, when the first inorganic insulating particles 19 are connected to each other to form the inorganic insulating layer 14, the content ratio of the second inorganic insulating particles 20 in the first region 26 can be made lower than the content ratio of the second inorganic insulating particles 20 in the second region 27.

When the slurry 36 is applied to the second uncured resin layer 31, by appropriately adjusting the degree of cure of the uncured resin, the size of the space in the uncured resin caused by the solvent 35 is adjusted, whereby the amount of entrance into the space by the second inorganic insulating particles 20 can be adjusted. Moreover, by appropriately adjusting the degree of cure of the uncured resin, the thickness of the first region 26 can be appropriately adjusted.

Moreover, since the third inorganic insulating particles 21 are present as the second filler in the second uncured resin layer 31 from the beginning, the first region 26 containing the third inorganic insulating particles 21 can be formed.

In the present embodiment, the slurry 36 containing the plurality of first inorganic insulating particles 19 whose particle diameter is not less than 3 nm and not more than 15 nm and the solvent 35 in which the first inorganic insulating particles 19 are dispersed is applied onto the support sheet 30. As a consequence, since the particle diameter of the first inorganic insulating particles 19 is not less than 3 nm and not more than 15 nm, some of the plurality of first inorganic insulating particles 19 can be firmly connected to each other even under low temperature conditions. It is assumed that this happens because the atoms of the first inorganic insulating particles 19, particularly, the atoms on the surface vigorously move since the first inorganic insulating particles 19 are minute and this lowers the temperature at which some of the first inorganic insulating particles 19 are firmly connected to each other.

Consequently, the plurality of first inorganic insulating particles 19 can be firmly connected to each other under low temperature conditions such as less than the crystallization start temperature of the first inorganic insulating particles 19, and further, not more than 250° C. Moreover, by performing heating at a low temperature as mentioned above, the first inorganic insulating particles 19 can be connected to each other only in an adjacent region while the particle shape of the inorganic insulating particles 16 is maintained. As a consequence, a neck structure is formed at the connection portions, and the gap 17 which is an open pore can be easily formed. The temperature at which the first inorganic insulating particles 19 can be firmly connected to each other is, for example, approximately 150° C. when the average particle diameter of the first inorganic insulating particles 19 is set to 15 nm.

Moreover, in the present embodiment, the slurry 36 further containing the plurality of third inorganic insulating particles 21 whose particle diameter is not less than 0.5 μm and not more than 5 μm, is applied onto the support sheet 30. As a consequence, since the space of the inorganic insulating particles 16 in the slurry 36 can be reduced by the third inorganic insulating particles 21 whose particle diameter is larger than those of the first inorganic insulating particles 19 and the second inorganic insulating particles 20, the contraction of the powder layer 37 formed by evaporating the solvent 35 can be reduced. Consequently, by reducing the contraction of the powder layer 37 having a flat shape which is apt to largely contract in the main surface direction, crack occurrence in the thickness direction in the powder layer 37 can be reduced.

Moreover, in the present embodiment, the slurry 36 further containing the plurality of second inorganic insulating particles 20 whose particle diameter is not less than 35 μm and not more than 110 μm, is applied onto the support sheet 30. As a consequence, the space of the inorganic insulating particles 16 in the regions between the third inorganic insulating particles 21 of the slurry 36 can be reduced by the second inorganic insulating particles 20 whose particle diameter is larger than that of the first inorganic insulating particles 19 and smaller than that of the second inorganic insulating particles 20. Consequently, crack occurrence in the regions between the third inorganic insulating particles 21 of the powder layer 37 can be reduced.

The content ratio of the inorganic insulating particles 16 in the slurry 36 is, for example, not less than 10% by volume and not more than 50% by volume, and the content ratio of the solvent 35 in the slurry 36 is, for example, not less than 50% by volume and not more than 90% by volume. For the solvent 35, for example, methanol, isopropanol, methyl ethyl ketone, methyl isobutyl ketone, xylene, or an organic solvent containing a mixture of two or more kinds selected therefrom can be used. Above all, methyl isobutyl ketone is preferably used as the solvent 35. As a consequence, the second resin layer 15 can be appropriately dissolved or swelled, so that a desired first region 26 can be obtained.

The heating temperature when the powder layer 37 is heated is not less than the boiling point of the solvent 35 and less than the crystallization start temperature of the first inorganic insulating particles 19, further, not less than 100° C. and not more than 250° C. Moreover, the heating time is, for example, not less than 0.5 hours and not less than 24 hours.

The applied pressure when the laminated inorganic insulating layer 14 and first uncured resin layer 32 are heated and pressurized is, for example, not less than 0.05 MPa and not more than 0.5 MPa, the pressurization time is, for example, not less than 20 seconds and not more than 5 minutes, and the heating temperature is, for example, not less than 50° C. and not more than 100° C. Since this heating temperature is less than the curing start temperature of the first uncured resin layer 32, the first uncured resin layer 32 can be maintained in uncured state.

(3) As shown in FIG. 6(b) to FIG. 6(c), the laminated sheet 33 is laminated on the core substrate 5 to form the insulating layer 10, and the via conductor 12 passing through the conductive layer 11 disposed on the insulating layer 10 and the insulating layer 10 in the thickness direction thereof is formed. Specifically, this is performed, for example, as follows:

First, the laminated sheet 33 is laminated on the core substrate 5 while the first uncured resin layer 32 is disposed on the side of the core substrate 5. Then, by heating and pressurizing in the thickness direction the core substrate 5 and the laminated sheet 33 which are laminated, the laminated sheet 33 is bonded to the core substrate 5. Then, as shown in FIG. 6(b), by heating the first uncured resin layer 32 and the second uncured resin layer 31, the uncured resin is cured to make the first uncured resin layer 32 the first resin layer 13 and make the second uncured resin layer 31 the second resin layer 15. As a consequence, the insulating layer 10 having the first resin layer 13, the inorganic insulating layer 14 and the second resin layer 15 can be formed. In this case, part of the first uncured resin layer 32 having entered the gap 17 becomes the second resin portion 29, and part of the second uncured resin layer 31 having entered the gap 17 becomes the first resin portion 28.

Then, the support sheet 30 is mechanically or chemically removed from the insulating layer 10. Then, using laser processing, a via hole passing through the insulating layer 10 in the thickness direction thereof is formed. When this is done, the conductive layer 11 is exposed at the bottom surface of the via hole. Then, as shown in FIG. 6(c), using electroless plating or electrolytic plating, a conductive material is made to adhere to the inner wall of the via hole and the exposed one main surface of the insulating layer 10 to thereby form the conductive layer 11 and the via conductor 12.

For the heating and pressurization when the core substrate 5 is bonded to the laminated sheet 33, conditions similar to those of step (2) may be used. The heating temperature when the uncured resin is cured is, for example, not less than the curing start temperature of the uncured resin and less than the thermal decomposition temperature, and the heating time is, for example, not less than 10 minutes and not more than 120 minutes.

(4) As shown in FIG. 6(d), by repeating steps (2) and (3), the buildup layers 6 are formed on the core substrate 5 to produce the wiring board 3. By repeating these steps, the buildup layers 6 can be made more multi-layered.

(5) By flip-chip mounting the electronic component 2 on the wiring board 3 through the bump 4, the mounting structure 1 shown in FIG. 1(a) is produced. The electronic component 2 may be electrically connected to the wiring board 3 by wire bonding or may be incorporated in the wiring board 3.

The invention is not limited to the above-described embodiment and various modifications, improvements, combinations and the like are possible without departing from the scope of the invention.

For example, while in the above-described embodiment of the invention, by way of example, there is described a structure in which the buildup layers 6 have the first resin layer 13, the inorganic insulating layer 14 and the second resin layer 15, the core substrate 5 may have a structure corresponding to the first resin layer 13, the inorganic insulating layer 14 and the second resin layer 15.

Moreover, while in the above-described embodiment of the invention, there is described an example using as the wiring board 3 a buildup multi-layer board composed of the core substrate 5 and the buildup layers 6, a different board may be used as the wiring board 3; for example, a single-layer board consisting only of the core substrate 5 or a coreless substrate consisting only of the buildup layers 6 may be used.

Moreover, while in the above-described embodiment of the invention, by way of example, there is described a structure in which the inorganic insulating particles 16 contain the third inorganic insulating particles 21, the inorganic insulating particles 16 do not necessarily contain the third inorganic insulating particles 21.

While in the above-described embodiment of the invention, an example structured so that the via conductors 12 adhere to the inner walls of the via holes is described, a structure in which the via conductors 12 are filled in the via holes may be used.

Moreover, while in the above-described embodiment of the invention, by way of example, there is described a structure in which the evaporation of the solvent 35 and the heating of the powder layer 37 are separately performed at step (2), these may be simultaneously performed.

### REFERENCE SIGNS LIST

1: Mounting structure
2: Electronic component
3: Wiring board
13: First resin layer
14: Inorganic insulating layer
15: Second resin layer
16: Inorganic insulating particle
17: Gap
18: Resin portion
19: First inorganic insulating particle
20: Second inorganic insulating particle
21: Third inorganic insulating particle
22: First resin
23: First filler particle
24: Second resin
25: Second filler particle
26: First region of inorganic insulating layer
27: Second region of inorganic insulating layer
28: First resin portion
29: Second resin portion
30: Support sheet
31: second uncured resin layer
32: First uncured resin layer
33: Laminated sheet

1. A wiring board, comprising:
a first resin layer;
an inorganic insulating layer disposed on the first resin layer;
a second resin layer disposed on the inorganic insulating layer; and
a conductive layer disposed on the second resin layer, the inorganic insulating layer containing
a plurality of first inorganic insulating particles partly connected to each other and having a particle diameter of not less than 3 nm and not more than 15 nm;
a plurality of second inorganic insulating particles existing with the first inorganic insulating particles in between and having a particle diameter of not less than 35 nm and not more than 110 nm; and
a resin portion disposed in a gap between the plurality of first inorganic insulating particles, and
the inorganic insulating layer having a first region located in a vicinity of the second resin layer and a second region located on a side opposite to a second resin layer side of the first region, and
a content ratio of the second inorganic insulating particles in the first region being lower than a content ratio of the second inorganic insulating particles in the second region.

2. The wiring board according to claim 1,
wherein the second resin layer is lower in Young's modulus than the first resin layer.

3. The wiring board according to claim 1,
wherein the first region contains, of the first inorganic insulating particles and the second inorganic insulating particles, only the first inorganic insulating particles.

4. The wiring board according to claim 1,
wherein the resin portion has a first resin portion disposed in the first region, and
the first resin portion is formed of a same resin as a second resin forming the second resin layer.

5. The wiring board according to claim 1,
wherein the resin portion has a second resin portion disposed in the second region, and
the second resin portion is formed of a same resin as a first resin forming the first resin layer.

6. The wiring board according to claim 1,
wherein the first resin layer contains a first resin and a plurality of first filler particles dispersed in the first resin,
the second resin layer contains a second resin and a plurality of second filler particles dispersed in the second resin, and
a content ratio of the second filler particles in the second resin layer is lower than a content ratio of the first filler particles in the first resin layer.

7. The wiring board according to claim 1,
wherein a thickness of the first region is smaller than a thickness of the second region.

8. A mounting structure, comprising:
the wiring board according to claim 1; and
an electronic component mounted on the wiring board and electrically connected to the conductive layer.

9. A laminated sheet, comprising:
a support sheet;
an uncured resin layer disposed on the support sheet; and
an inorganic resin layer disposed on the uncured resin layer, the inorganic insulating layer containing
a plurality of first inorganic insulating particles partly connected to each other and having a particle diameter of not less than 3 nm and not more than 15 nm; and
a plurality of second inorganic insulating particles existing with the first inorganic insulating particles in between and having a particle diameter of not less than 35 nm and not more than 110 nm,
the inorganic insulating layer having a first region located in a vicinity of the uncured resin layer and a second region located on a side opposite to a uncured resin layer side of the first region, and
a content ratio of the second inorganic insulating particles in the first region being lower than a content ratio of the second inorganic insulating particles in the second region.

10. The laminated sheet according to claim 9,
wherein in a gap between the first inorganic insulating particles in the first region, a same resin as a resin forming the uncured resin layer is disposed.
